(19) United States
(12) Patent Application Publication
(10) Pub. No.: US 2008/0101912 A1
(43) Pub. Date: May 1, 2008

(54) DEPOSITION ANALYSIS FOR ROBOT MOTION CORRECTION

(76) Inventors: Todd W. Martin, Mountain View, CA (US); Steven V. Sansoni, Livermore, CA (US); Michael R. Rice, Pleasanton, CA (US); Eric Ng, Mountain View, CA (US); Jeffrey C. Hudgens, San Francisco, CA (US); Frederick Guckel, Pleasanton, CA (US); Russel Kaplan, Sunnyvale, CA (US)

Correspondence Address: Patterson & Sheridan, LLP, Suite 1500, 3040 Post Oak Boulevard, Houston, TX, 77056, US

(21) Appl. No.: 11/553,113

(22) Filed: Oct. 26, 2006

(51) Int. Cl. H01L 21/66; G01R 31/26

(52) U.S. Cl. 414/935; 414/939; 438/14

(57) ABSTRACT

Methods for correcting motion of a robot are provided in the present invention. In one embodiment, a method for correcting motion of a robot includes transferring a first substrate supported on a robot to a processing position using a robotic motion routine, depositing a material on the first substrate in the processing position, determining an offset between a center of the deposited material and a center of the first substrate, adjusting the robotic motion routine to compensate for the offset. In another embodiment, a processing chamber is provided configured to obtain samples from which motion of a robot operated therein may be corrected to improve substrate placement on a substrate support through analysis of material deposited on the substrate.

### BACKGROUND OF THE INVENTION

1. Field of the Invention

The present invention generally relates to methods for detecting errors in substrate placement and the correction thereof. More specifically, the present invention generally relates to methods detecting errors in robot motion by analysis of material deposited on a substrate.

2. Description of the Related Art

Reliably producing sub-half micron and smaller features is one of the key technologies for the next generation of very large scale integration (VLSI) and ultra large-scale integration (ULSI) of semiconductor devices. However, as the limits of circuit technology are pushed, the shrinking dimensions of interconnects in VLSI and ULSI technology have placed additional demands on processing capabilities. Reliable placement of a substrate in processing chambers utilized to fabricate VLSI and ULSI devices is critical for enabling increased circuit density and quality of individual substrates and die in next generation devices.

Conventionally, a robot utilized to place a substrate in a processing chamber relies on sensors to detect the true position of robot or substrate carried thereon, and compares the sensed true position with an expected position based on the angular position of the robot motor(s). The difference between the expected and sensed position of the robot or substrate carried thereon may be utilized to correct the robots motion. Although this methodology generally provides good motion control, little is known about the position of the substrate once the substrate is transferred to a substrate support pedestal from the robot. Since the position of the substrate on the substrate support pedestal is ultimately the important factor for achieving robust processing results, the inventors have realized that it would be beneficial to know not only if the substrate is in an expected position while on the robot, but also if the substrate was actually positioned correctly on the substrate support. Particularly in hot processing chambers and at low vacuum pressures, distortion and thermal expansion of chamber components and robot linkages may significantly change the length and sag of the robot linkages along with the true position of the substrate support, making accurate placement of the substrate a substantial challenge. If the substrates position relative to the substrate support can be determined, then the robot placement routine may be adjusted (e.g., corrected) to ensure that subsequently processed substrates are correctly positioned on the substrate support.

Therefore, there is a need for an improved method for determining the position of a substrate relative to a substrate support, and to utilize such information to correct a motion routine of a robot so that a substrate may be accurate transferred to the substrate support.

### SUMMARY OF THE INVENTION

Methods for correcting motion of a substrate positioning mechanism are provided in the present invention. In one embodiment, a method for correcting motion of a substrate positioning mechanism includes transferring a first substrate supported on a substrate positioning mechanism to a processing position using an automated motion routine, depositing a material on the first substrate in the processing position, determining an offset between a center of the deposited material and a center of the first substrate, and adjusting the automated motion routine to compensate for the offset.

In another embodiment, a method for correcting motion of a substrate positioning mechanism disposed in a semiconductor processing system, wherein the processing system includes at least one vacuum transfer chamber housing the substrate positioning mechanism, a load lock chamber coupled to the transfer chamber and at least one processing chamber coupled to the transfer chamber is provided that includes transferring a first substrate supported on the substrate positioning mechanism to a processing position using a first motion routine, depositing a material on the first substrate, sensing a metric indicative of a lateral position of the deposited material relative to the substrate while transferring the first substrate from the processing position using a second motion routine, and adjusting first motion in response to the metric.

In another embodiment, a method for correcting motion of a substrate positioning mechanism includes depositing a material on a substrate at a processing position, sensing a metric indicative of a lateral position of the deposited material relative to the substrate, and adjusting a motion routing in response to the metric.

In yet another embodiment of the invention, a processing system is provided that includes at least one load lock chamber and at least one processing chamber coupled to a transfer chamber having a substrate positioning mechanism disposed therein. At least one sensor is interfaced with a controller and arranged to obtain a metric indicative of a lateral position of a substrate relative to material deposited thereon. A computer-readable medium is provided having stored thereon a plurality of instructions. The plurality of instructions includes instructions, which, when executed by the controller, cause the processing system to perform the steps of depositing a material on a substrate at a processing position, sensing a metric indicative of a lateral position of the deposited material relative to the substrate, and adjusting a motion routing in response to the metric.

In still another embodiment of the invention, a method for correcting motion of a substrate positioning mechanism includes processing a material on a substrate at a processing position, wherein the processing produces a processing profile, sensing a metric indicative of a lateral position of the processing profile relative to the substrate, and adjusting motion routine of the substrate positioning mechanism in response to the metric.

### BRIEF DESCRIPTION OF THE DRAWINGS

The teachings of the present invention can be readily understood by considering the following detailed description in conjunction with the accompanying drawings, in which:

FIG. 1 is one embodiment of an exemplary processing chamber in which the invention may be practiced;

FIG. 2 is one embodiment of a substrate illustrating the misalignment between the perimeter of the substrate and a deposition pattern present on the backside of the substrate;

FIGS. 3-4 are partial sectional views of another embodiment of a substrate support and a substrate processed thereon illustrating misalignment between the perimeter of the substrate and a deposition pattern present on the front side of the substrate;

FIG. 5 is an exemplary processing system which may be utilized to practice the method of the present invention;

FIGS. 6A-B are embodiments of a substrate supported on a substrate transfer robot passing through sensing regions of the processing system of FIG. 5;

FIGS. 7A-B depict substrates carried by the substrate transfer robot passing through the sensing regions respectfully illustrated in FIGS. 6A-B; and

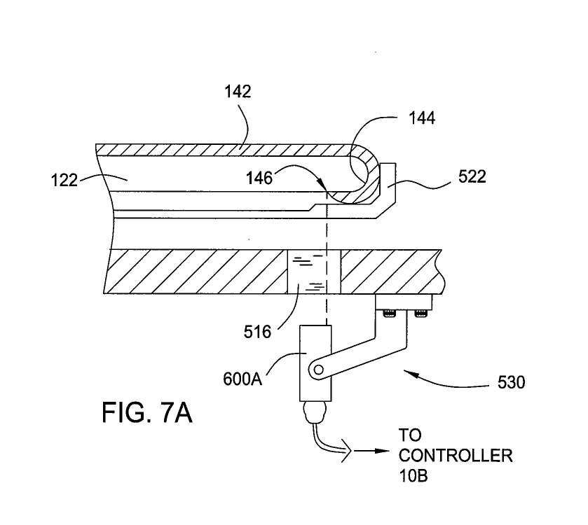

FIG. 8 is another embodiment of a substrate supported on a substrate transfer robot passing through a sensing region of a processing system.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

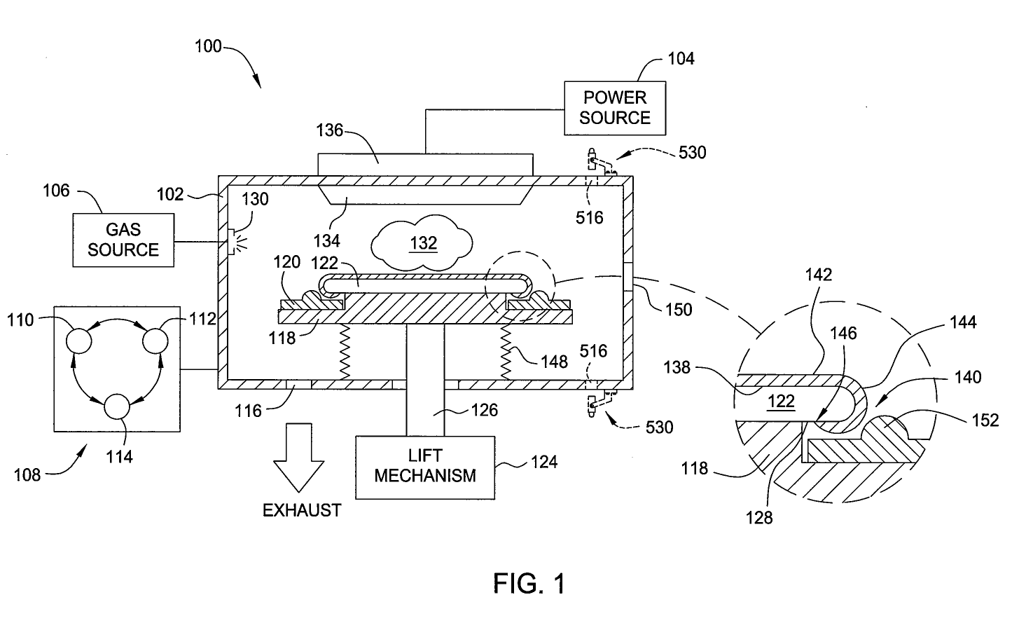

FIG. 1 depicts one embodiment of a semiconductor processing chamber 100. Although the processing chamber 100 is illustratively shown as a physical vapor deposition (PVD) chamber, the processing chamber 100 may also be a chemical vapor deposition (CVD) chamber, an atomic layer deposition (ALD) chamber, an electroless deposition chamber, an etching chamber, an electroplating chamber or other processing chamber or module utilized to deposit or etch films on a substrate. The processing chamber 100 includes a chamber body 102 coupled to a power source 104, a gas source 106 and a controller 108. The controller 108 is utilized to control the operations of the processing chamber 100 and may be utilized to control and/or correct robotic motion as further described below.

The controller generally includes a memory 110, a CPU 112 and support circuits 114. The CPU 112 may be one of any form of computer processor that can be used in an industrial setting for controlling various chambers and subprocessors. The memory 110 is coupled to the CPU 112. The memory 110, or computer-readable medium, may be one or more of readily available memory such as random access memory (RAM), read only memory (ROM), floppy disk, hard disk, or any other form of digital storage, local or remote. The support circuits 114 are coupled to the CPU 112 for supporting the processor in a conventional manner. These circuits include cache, power supplies, clock circuits, input/output circuitry, subsystems, and the like.

The chamber body 102 generally includes an exhaust port 116 which is coupled to a pumping system (not shown) and a substrate transfer port 150. The substrate transfer port 150 is utilized to allow robotic entry and egress of a substrate 122 from the chamber body 102.

A substrate support pedestal 118 is disposed in the chamber body 102. The substrate support pedestal 118 is coupled to a lift mechanism 124 by a rod 126. The lift mechanism 124 controls the elevation of the substrate support pedestal 118, typically between a lowered transfer position and an elevated processing position. Bellows 148 are typically coupled between the pedestal 118 and the bottom of the chamber body 102, and circumscribes the rod 126 to prevent leakage from the processing chamber 100.

An edge ring 120 is supported on the perimeter region of the pedestal 118. A portion of the edge ring 120 generally extends below a perimeter 144 of the substrate 122. The edge ring 120 has a projection 152 extending upward therefrom, which bounds one side of a gap 140 defined between the projection 152 of the ring 120 and the perimeter 144 of the substrate 122.

A target 134 is coupled to the ceiling of the chamber body 102. The target 132 is coupled to the power source 104. The target is typically comprised from a material which is sputtered onto the substrate 122 during processing. A magnetron 136 is generally coupled to the top of the chamber body 102 above the target 134 to enhance efficient usage of the target 134 and uniformity of deposition on the substrate 122.

In operation, a process gas is provided from the gas source 106 through one or more gas ports 130 formed through the chamber body 102. Power is applied to the target 134 by the power source 104 and a plasma 132 is formed from the process gas. Ions from the plasma strike the target 134 and sputter off material which then is deposited as deposition material 142 on the front side 138 of the substrate 122. Some sputtered material enters the gap 140 and deposits on the perimeter 144 and backside 128 of the substrate 122.

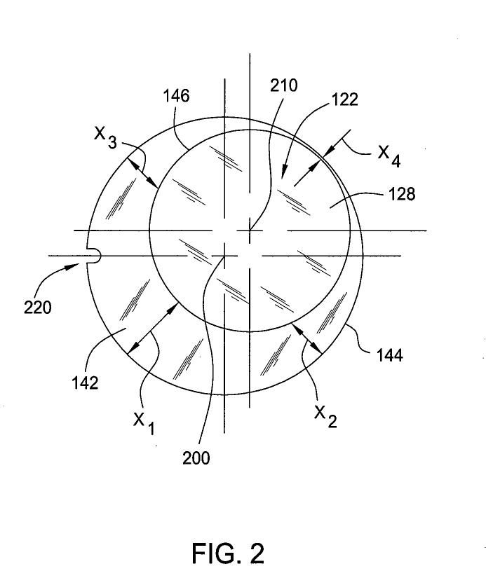

As depicted in the bottom view of the substrate 122 in FIG. 2, the edge 146 of the deposited material 142 present on the backside 128 of the substrate 122 may be non-concentric to the perimeter 144 of the substrate 122. This is often because the substrate 122 was not positioned correctly with respect to the substrate support pedestal 128 and/or the edge ring 120. The non-concentricity between the edge 146 and perimeter 144 is illustrated by the offset between the center of the substrate 122 relative to the center of the edge 146 of the deposited material 142, as shown in FIG. 2 by center lines 200, 210.

The inventors have discovered that by determining the offset between centers of the edge 146 of the deposited material 142 and the perimeter 144 of the substrate 122, the motion of the robot placing the substrate 122 on the substrate support pedestal 118 may be corrected to concentrically align the deposited material on subsequently processed substrates. For example, a plurality of distances between the edge 146 and the perimeter 144 of the substrate, as shown by distance X₁, X₂, X₃ and X₄, may be measured relative to a reference point, such as a notch 220 formed in the substrate 122, to calculate the offset between the centers 200, 210. The offset information may be utilized to correct the robot motion. In a simple embodiment, the distance X₁, X₂, X₃ and X₄ may be measured using hand or other tools outside the processing chamber 100, and a correction for the robot motion may be provided to the controller 108. This process may also be automated in a variety of ways.

The method of using an offset between the centers of the deposited material and the substrate may also be utilized to correct the substrate placement in systems where the edge of the deposited material is present on the front side of the substrate. Such embodiments are representative of processing systems which use a shadow ring to cover the edge of the substrate.

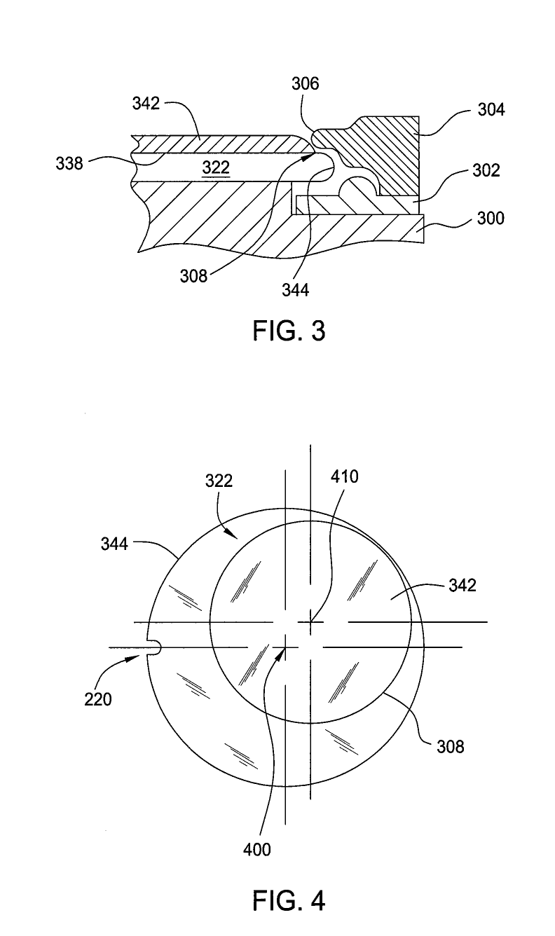

For example, FIGS. 3-4 depict a partial sectional view of a substrate support pedestal 300 having a cover ring 302 which underlies a portion of a substrate 322. A shadow ring 304 is disposed on the cover ring 302 and has a lip 306 which extends over a perimeter 344 of the substrate 322. During processing, deposited material 324 is deposited on the front side 338 of the substrate 332. The lip 306 of the shadow ring 304 prevents deposition on the perimeter 344 of the substrate. Thus, the deposited material 342 has an edge 308 generally just inward of the perimeter 344 on the front side 338 of the substrate.

As illustrated in FIG. 4, a center 410 of the deposited material 324 may be offset from a center 400 of the substrate 322. Measuring the offset between the centers 400, 410, as discussed above, may be utilized to correct the position of the substrate 322 on the pedestal 300 so that the deposited material 342 is concentrically deposited on the substrate 322.

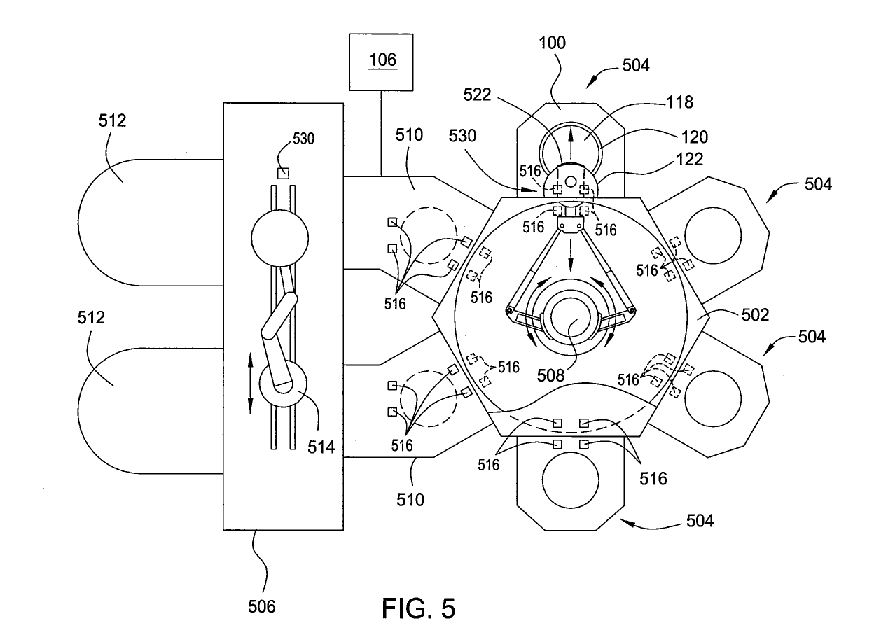

FIG. 5 depicts one embodiment of a processing system 500 in which embodiments of the present invention may be practiced. The processing system 500 generally includes a vacuum transfer chamber 502 having a plurality of processing chambers 504 coupled thereto. In one embodiment, at least one of the processing chambers 504 is a deposition chamber, such as the processing chamber 100 depicted in FIG. 1. In another embodiment, at least one of the processing chambers 504 is an etch chamber, as utilized in an alternative embodiment of the invention discussed further below. At least one load lock chamber 510 is coupled between the transfer chamber 502 and a factory interface 506 to facilitate transferring substrates from the atmospheric environment of the factory interface 506 and the vacuum environment of the transfer chamber 502. In the embodiment depicted in FIG. 5, two load lock chambers 510 are depicted.

The factory interface 506 generally includes an atmospheric robot 514 and a plurality of bays adapted to receive a substrate storage cassette 512. The robot 514 is utilized to transfer substrates between the load lock chambers 510 and substrate storage cassettes 512.

A vacuum robot 508 is disposed in the transfer chamber 502 and facilitates transferring substrates between the processing chambers 504 and the load lock chamber 510. In one embodiment, the vacuum robot 508 is a frog-leg robot having a blade 522 which supports a substrate 122 thereon during substrate transfer. It is contemplated that other types of robots may be utilized. Motion of the robot is generally controlled by the controller 106 coupled to the processing system 500.

The processing system 500 includes at least one sensing system 530 suitable for detecting a metric indicative of an offset between centers of the deposited material and the substrate 122. The indicative metric may be the edge of the substrate and deposited material, an image of the entire substrate and edge of deposited material, an image of a portion of the substrate and edge of the deposited material, electrical properties of the deposited films at the edge (such as Sheet Resistance (Rs), continuity, resistivity and the like), taper of the edge of the deposited material, change material thickness, reflectivity or other metric suitable for determining a positional relation between the deposited material and the substrate that may be utilized to determine a robot correction. The sensing system 530 generally includes a sensor (not shown in FIG. 5) which is suitable for detecting the perimeter 144 (344) of the substrate 122 (344) and the edge 146 (308) of the deposited material 142 (342). In the embodiment depicted in FIG. 5, the sensing system 530 generally includes at least one window 516 which is positioned to enable the sensor to view the substrate. To enhance throughput, the sensor and window 516 may be positioned to view the substrate while carried by one of the robots 508, 514, although the substrate may be viewed at other locations or while the substrate is disposed on objects other than the robot. As shown in the embodiment depicted in FIG. 5, the windows 516 may be disposed on the floor and/or ceiling of at least one of the processing chambers 504, transfer chamber 502, load lock chamber 510 or factory interface 506.

The windows 516 may be fabricated from a material transmissive to the sensor such that the sensor may interface with the substrate. One such window material is quartz or sapphire. It is contemplated that in regions outside of vacuum, such as in the factory interface 506, the window 516 may be simply an open aperture or an aperture covered by a transmissive glass or plastic material.

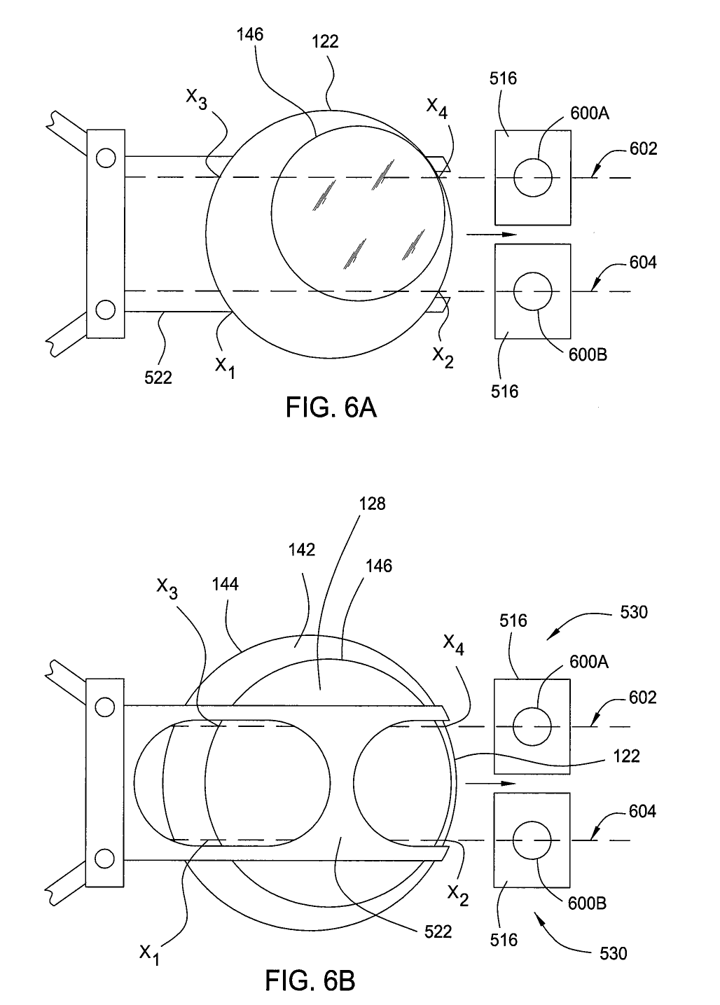

FIG. 6A depicts one embodiment of the sensing system 530 configured to view the face 338 of the substrate 332 while supported on the blade 522 of the robot 508 (or robot 514). The sensing system 530 depicted in FIG. 6A includes at least one window 516 positioned such that the substrate 322, when passed below the window 516 while supported on the robot blade 522, passes below through the sensing field of the one or more sensors. In the embodiment depicted in FIG. 6A, sensors 600A, 600B are shown. As the substrate moves through the sensing field, the leading and trailing edges of the substrate pass below the sensors 600A, 600B. This allows each sensor to obtain multiple samples during one pass of the robot through the sensing field. It is contemplated that one or more sensors may be used to obtain multiple samples by using the robot reposition of the substrate for each sample. It is contemplated that one or more sensors may be used to obtain one or more sample images from which the offset may be resolved.

In the embodiment depicted in FIG. 6A, the edge 308 and the perimeter 344 may be detected by the sensor 600A to measure at distances X₃, X₄, as shown by dotted line 602. The sensor 600B is positioned to detect the edge 308 and the perimeter 344 of the substrate to resolve distances X₁, X₂, as shown by dotted line 604. As discussed above, distances X₁-X₄ may be used to determine the offset between the centers of the edge of the deposited material and the edge of the substrate. This information may be utilized to correct the placement of the substrate on the pedestal 118 so that the deposition edge 308 is concentric with the substrate 332. As the sensors 600A, 600B are viewing the front side 338 of the substrate 332, the windows 516 are typically positioned in the top of at least one of the processing chambers (as shown in phantom as indicated by reference numeral 516 in FIG. 1) the transfer chamber or the load lock chamber. A window may be provided in the factory interface or load lock chamber 510 to correct the positioning of the substrate.

FIG. 6B depicts a substrate 122 supported on the blade 522 such that the backside 128 of the substrate 122 is shown. Windows 516 are located in the bottom of the processing system 500 to allow at least one sensor of the system 530 to view the backside 128 of the substrate 122 as the substrate 122 is passed thereover. In the embodiment depicted in FIG. 6B, two sensors 600A, 600B are shown.

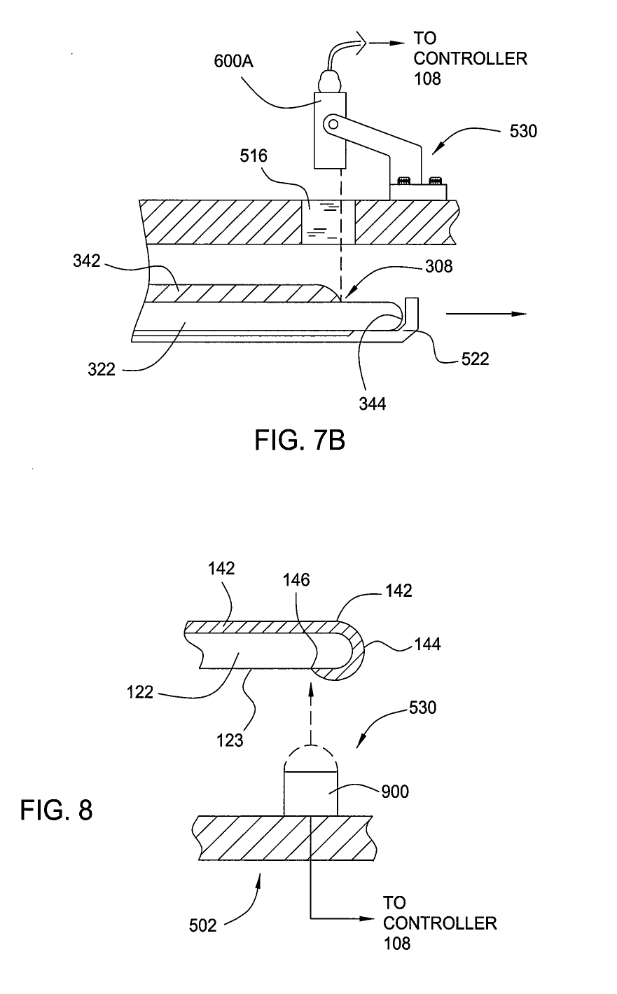

The sensors 600A, 600B may generally be any sensors suitable for detecting the edge of the deposited material and the edge of the substrate. In one embodiment, the sensor senses reflectivity. In another embodiment, the sensor may detect changes in color or grayscale that is indicative of the edge of the deposited material and edge of the substrate. In yet another embodiment, the sensor may detect changes in the height or taper at the interface between the deposited material and the substrate. In yet another embodiment, the sensor may be a stylus, mechanical switch, proximity sensor, linear displacement transducer or other sensor suitable for detecting geometric differences between the deposited film and the substrate. In yet another embodiment, the sensor may be a continuity sensor, resistivity sensor or other sensor suitable for detecting electrical properties which may be utilized to detect the interface between the deposited film and the substrate. In yet another embodiment, the sensor may be a camera or other image capturing device. In embodiments wherein the sensor is a camera, machine vision techniques may be utilized to determine the offset in concentricity. The camera may view the entire substrate at once or by viewing portions of the substrate. For example, an image of a portion of the edge (of the substrate or deposited material) may be utilized to determine the radius, and thus the center. By obtaining at least data points indicative of the circumference of the edge 146 of the deposited material 142 and the edge perimeter 144 of the substrate, the centers of the deposited material and the substrate may be determined. The offset between the centers may be utilized to correct the position of subsequent substrates on the pedestal so that the concentricity between the deposition area and the substrate is improved. It is also contemplated that a sensor 800 of the sensing system 530 may be disposed inside the processing system 500. For example, as depicted in FIG. 8, a sensor 800 is disposed inside the transfer chamber 502 and coupled to the controller 108 through a vacuum-tight feedthrough, without need for a window.

In another embodiment of the invention, the sensing system 530 may be utilized with in an etch system to determine offsets between the substrate placement on a substrate support and a center of processing. For example, a center to edge process profile, such etch rate, microloading, polymerization, etch depth, CD bias and the like, may not be concentric with the substrate. By sensing a metric indicative of the process profile, the center of the process profile may be resolved relative to the center of the substrate. Utilizing this information, the robotic motion utilized to place the next substrate to be processed on the substrate support may be corrected such that the process profile is concentric with the substrate.

Although the substrate placement correction process is described above for correcting the motion of a substrate transfer robot, the method may be utilized to center a substrate relative a process condition utilizing other motion control devices, such as linear actuator, x/y tables and the like.

Thus, the present invention provides an improved method for determine the placement of substrates on a substrate support. The method described herein advantageously facilitates obtaining information for utilization for robot calibration and correction in a non-invasive manner that is transparent to throughput considerations.

While the foregoing is directed to embodiments of the present invention, other and further embodiments of the invention may be devised without departing from the basic scope thereof, and the scope thereof is determined by the claims that follow.

What is claimed is:

1. A method for correcting motion of a substrate positioning mechanism, comprising:
transferring a first substrate supported on a substrate positioning mechanism to a processing position using an automated motion routine;
depositing a material on the first substrate in the processing position;
determining an offset between a center of the deposited material and a center of the first substrate; and
adjusting the automated motion routine to compensate for the offset.

2. The method of claim 1, wherein determining the offset further comprises:
determining a distance between an edge of the deposited material and an edge of the substrate.

3. The method of claim 1, wherein determining the offset further comprises:
inspecting the substrate outside of a processing system in which the substrate positioning mechanism is positioned.

4. The method of claim 1, wherein determining the offset further comprises:
inspecting the substrate inside of a processing system in which the substrate positioning mechanism is positioned.

5. The method of claim 1, wherein determining the offset further comprises:
determining, in a plurality of locations on the substrate, a distance between an edge of the deposited material and an edge of the substrate.

6. The method of claim 1, wherein determining the offset further comprises:
passing the substrate carried by the substrate positioning mechanism below a sensor; and
obtaining, using the sensor, a metric indicative of the center of the deposited material.

7. The method of claim 1, wherein determining the offset further comprises:
determining a curvature of an edge of the deposited material.

8. The method of claim 1, wherein determining the offset further comprises:
optically detecting an edge of the deposited material.

9. The method of claim 8, wherein optically detecting the edge of the deposited material further comprises:
viewing the edge of the deposited material with a camera.

10. The method of claim 8, wherein optically detecting the edge of the deposited material further comprises:
sensing a change in reflectivity between the deposited material and a portion of the substrate not covered by the deposited material.

11. The method of claim 1, wherein determining the offset further comprises:
capturing an image of at least a portion of an edge of the deposited material and a perimeter of the substrate.

12. The method of claim 1, wherein determining the offset further comprises:
obtaining at least one sample indicative of an edge of the deposited material from a backside of the substrate.

13. The method of claim 1 further comprising:
adjusting a second automated motion routine utilized to move the first substrate to a second processing position.

14. The method of claim 1 further comprising:
transferring a second substrate to the first processing position utilizing the adjusted first automated motion routine.

15. The method of claim 1 further comprising:
correcting at least one of an alignment of a processing kit within the processing chamber or setting a flag to stop processing.

16. The method of claim 1, wherein determining the offset further comprises:
determining position of the deposited material by an electrical characteristic of the material.

17. A method of correcting motion of a substrate positioning mechanism disposed in a semiconductor processing system, wherein the processing system includes at least one vacuum transfer chamber housing the substrate positioning mechanism, a load lock chamber coupled to the transfer chamber and at least one processing chamber coupled to the transfer chamber, comprising:
transferring a first substrate supported on the substrate positioning mechanism to a processing position using a first motion routine;
depositing a material on the first substrate;
sensing a metric indicative of a lateral position of the deposited material relative to the substrate while transferring the first substrate from the processing position using a second motion routine; and
adjusting first motion in response to the metric.

18. The method of claim 17, wherein sensing further comprises:
passing the substrate over a window formed in a bottom of at least one of the transfer chamber, the load lock chamber and the processing chamber.

19. The method of claim 17, wherein transferring the first substrate to the inspection location within the processing system further comprises:
passing the substrate under a window formed in a top of at least one of the transfer chamber, the load lock chamber and the processing chamber.

20. The method of claim 17, wherein sensing the metric indicative of the lateral position of the deposited material relative to the substrate further comprises:
sensing a metric indicative of at least one of an edge or center of the deposited material.

21. The method of claim 17, wherein sensing the metric indicative of the lateral position of the deposited material relative to the substrate further comprises:
obtaining an image of at least a portion of the substrate.

22. The method of claim 17 further comprising:
correcting at least one of an alignment of a processing kit within the processing chamber or setting a flag to stop processing.

23. A method for correcting motion of a substrate positioning mechanism, comprising:
processing a material on a substrate at a processing position, wherein
the processing produces a processing result profile;
sensing a metric indicative of a lateral position of a center of the processing profile relative to a center or edge the substrate; and
adjusting motion routine of the substrate positioning mechanism in response to the metric.

24. The method of claim 23, wherein sensing further comprises:
viewing a backside of the substrate.

25. The method of claim 23, wherein sensing further comprises:
obtaining an image of the substrate.

26. The method of claim 23, wherein sensing further comprises:
sensing a metric indicative of an etch processing result.

27. The method of claim 23, wherein sensing further comprises:
sensing a metric indicative of deposition processing result.

28. A processing system, comprising:
a vacuum transfer chamber;
a robot disposed in the transfer chamber;
at least one load lock chamber coupled to the transfer chamber;
at least one processing chamber coupled to the transfer chamber;
a controller;
at least one sensor interfaced with the controller and arranged to obtain a metric indicative of a lateral position of a substrate relative to a center of a processing result of a process performed on the substrate; and
a computer-readable medium having stored thereon a plurality of instructions, the plurality of instructions including instructions which, when executed by the controller, cause the processing system to perform the steps of:
processing a material on the substrate at a processing position, wherein the processing produces a processing result;
sensing a metric indicative of a lateral position of the processing result relative to the substrate; and
adjusting a motion routine of the substrate positioning mechanism in response to the metric.
